(19) United States
(12) Patent Application Publication
(10) Pub. No.: US 2007/0012918 A1
(43) Pub. Date: Jan. 18, 2007

(54) Liquid crystal display device and optical film assembly for the liquid crystal display device

(75) Inventors: Jae-Young Lee, Yongin-si (KR); Won-Sang Park, Yongin-si (KR); Hae-Young Yun, Suwon-si (KR); Jae-Hyun Kim, Suwon-si (KR); Jae-Ik Lim, Seoul (KR); Seung-Hyu Lee, Yongin-si (KR); Ji-Youn Choi, Suwon-si (KR); Joo-Hee Oh, Suwon-si (KR); Hye-Jin Seo, Suwon-si (KR); Sung-Eun Cha, Geoje-si (KR); Young-Joo Chang, Suwon-si (KR); Sang-Woo Kim, Suwon-si (KR)

Correspondence Address: F. CHAU & ASSOCIATES, LLC, 130 WOODBURY ROAD, WOODBURY, NY, 11797, US

(73) Assignee: Samsung Electronics Co., Ltd., Suwon-si (KR)

(21) Appl. No.: 11/472,171

(22) Filed: Jun. 21, 2006

(30) Foreign Application Priority Data
Jun. 22, 2005 (KR) 2005-54175

(51) Int. Cl. H01L 29/04

(52) U.S. Cl. 257/59

(57) ABSTRACT

A liquid crystal display device is provided. The liquid crystal display device includes a liquid crystal display panel and an optical film assembly. The liquid crystal display panel includes two substrates and a liquid crystal layer disposed between the substrates, and has a plurality of multi-domains defined in a unit pixel. The optical film assembly includes a biaxial film and a polarizing film formed integrally with the biaxial film. Moreover, the biaxial film is disposed near to the liquid crystal cell.

### CROSS-REFERENCE TO RELATED APPLICATIONS

This application relies for priority upon Korean Patent Application No. 2005-54175 filed on Jun. 22, 2005, the contents of which are hereby incorporated by reference herein in its entirety.

### BACKGROUND OF THE INVENTION

1 . Field of the Invention

The present invention relates to a liquid crystal display device and an optical film assembly for the liquid crystal display device. More particularly, the present invention relates to a liquid crystal display device having a thin thickness and also to reducing the cost of manufacturing an optical film assembly for the liquid crystal display device.

2. Description of the Related Art

An LCD device may include, for example, an array substrate (or a TFT substrate) on which thin film transistors (TFTs) are formed for switching each pixel, an opposite substrate (or a color filter substrate) on which a common electrode is formed, and a liquid crystal layer disposed between the substrates. An LCD device displays an image by applying voltage to the liquid crystal layer, thereby controlling light transmittance.

The LCD device has a relatively narrow viewing angle because light is transmitted in a range, which is not blocked by the liquid crystal. Thus, to increase the viewing angle of an LCD device an LCD device may implement a vertically aligned (VA) mode.

For example, a conventional LCD device configured to implement a VA mode may include two substrates and a liquid crystal layer disposed between the two substrates. The liquid crystal layer may include, for example, a liquid crystal material having a dielectric constant anisotropy of a negative type. Moreover, the liquid crystal molecules of the liquid crystal layer may align in a homeotropic alignment mode.

When no voltage is applied to the substrates, during the operation of the above-mentioned conventional LCD device, the liquid crystal molecules align in a vertical direction to display a black color. However, when a predetermined voltage is applied to the substrates (e.g., to control electrodes of the array substrate and associated common electrodes of the color filter substrate), the liquid crystal molecules align in a horizontal direction to display a white color. Additionally, when a voltage less than the predetermined voltage is applied to the substrates, the liquid crystal molecules become inclined with respect to a surface of the substrates to display a gray color.

However, with conventional LCD devices, a narrow viewing angle and inversion of gradations may occur, particularly with small to medium sized LCD devices. To prevent the above-mentioned narrow viewing angle and gradation inversions from occurring, small to medium sized LCD devices have been configured to implement a patterned vertical alignment (PVA) mode structure. An LCD device having a PVA mode may include a common electrode layer patterned and formed on the color filter substrate and a pixel electrode layer patterned and formed on the array substrate.

When forming the PVA structure a process involving indium-tin oxide (ITO) patterning on the array substrate and color filter substrate may be required. However, to pattern an ITO layer separately when manufacturing a color filter, additional processes such as a photo process, a developing process, an etching process, and a PR strip process may also be required, thereby also increasing the costs for manufacturing the LCD device.

Thus, there is a need for an improved LCD device, which may also be manufactured at a reduced cost in comparison to conventional LCD devices.

### SUMMARY OF THE INVENTION

Embodiments of the present invention provide an optical film assembly having a reduced thickness to reduce the thickness of a liquid crystal display device having the optical film and also to reduce the cost of manufacturing the liquid crystal display device. Embodiments of the present invention also provide a liquid crystal display device having the optical film assembly.

According to an embodiment of the present invention, a liquid crystal display device is provided. The liquid crystal display device includes a liquid crystal display panel and an optical film assembly. The liquid crystal display panel includes two substrates and a liquid crystal layer disposed between the substrates. In addition, the liquid crystal display panel has a plurality of multi-domains defined in a unit pixel. The optical film includes a biaxial film and a polarizing film formed integrally with the biaxial film. The biaxial film is disposed near to the liquid crystal display panel. Moreover, the optical film assembly is disposed under and over the liquid crystal display panel.

According to an embodiment of the present invention, a liquid crystal display device is provided. The liquid crystal display device includes a liquid crystal display panel and an optical film assembly. The liquid crystal display panel includes two substrates and a liquid crystal layer disposed between the substrates. The liquid crystal molecules of the liquid crystal layer are aligned at an angle of about 90 degrees with respect to the substrates. The optical film assembly is disposed under and over the liquid crystal display panel. Additionally, the optical film includes a biaxial film and a polarizing film formed integrally with the biaxial film. The biaxial film is disposed relatively near to the liquid crystal display panel.

According to another embodiment of the present invention, an optical film assembly is provided. The optical film assembly includes a biaxial film and a polarizing film. The optical film assembly changes a characteristic of light provided through a liquid crystal cell. The biaxial film is disposed near to the liquid crystal cell. The polarizing film is disposed away from the liquid crystal cell. Furthermore, the polarizing film is formed integrally with the biaxial film.

According to the optical film assembly and the liquid crystal display device having the optical film assembly of embodiments of the present invention, a biaxial film, whose surface-wise directional retardation Ro is λ/4 and thickness-wise directional retardation Rth is about 160 nm, is disposed near to a liquid crystal display panel, and a polarizing film adheres to the biaxial film so that an optical film may be thin and the costs of manufacturing an optical film or a liquid crystal display device may be reduced.

### BRIEF DESCRIPTION OF THE DRAWINGS

Exemplary embodiments of the present invention can be understood in more detail from the following description taken in conjunction with the accompanying drawings, in which:

FIG. 1 is a plan view showing a portion of a liquid crystal display device according to an embodiment of the present invention;

FIG. 2 is a cross-sectional view taken along a line I-I′ in FIG. 1;

FIG. 3 is a cross-sectional view for explaining the operation of the liquid crystal display device shown in FIG. 1;

FIG. 4 is an image showing a texture observed in a liquid crystal display device having a multi-domain;

FIG. 5 is an image showing that the texture in FIG. 4 is eliminated by an optical film assembly according to an embodiment of the present invention;

FIG. 6 is a cross-sectional view to explain an optical film part, in particular, an upper optical film disposed on an upper substrate;

FIGS. 7, 8 and 9 are graphs to explain a viewing angle characteristic of a liquid crystal display device having an optical film according to an embodiment of the present invention;

FIGS. 10, 11 and 12 are graphs to explain a viewing angle characteristic of a liquid crystal display device having an optical film according to an embodiment of the present invention;

FIG. 13 is a graph to explain a viewing angle characteristic corresponding to a thickness-wise directional retardation Rth of about 160 nm along a thickness-wise direction of a biaxial film according to an embodiment of the present invention;

FIG. 14 is a graph to explain a viewing angle characteristic corresponding to a thickness-wise directional retardation Rth of about 600 nm along a thickness-wise direction of a biaxial film according to an embodiment of the present invention;

FIG. 15 is a graph to explain a viewing angle characteristic corresponding to a thickness-wise directional retardation Rth of about 320 nm along a thickness-wise direction of a biaxial film according to an embodiment of the present invention;

FIG. 16 is a cross-sectional view of a liquid crystal display device according to an embodiment of the present invention; and

FIG. 17 is a cross-sectional view showing simply the liquid crystal layer shown in FIG. 16.

### DESCRIPTION OF EXEMPLARY EMBODIMENTS

The invention is described more fully hereinafter with reference to the accompanying drawings, in which embodiments of the invention are shown. This invention may, however, be embodied in many different forms and should not be construed as limited to the embodiments set forth herein.

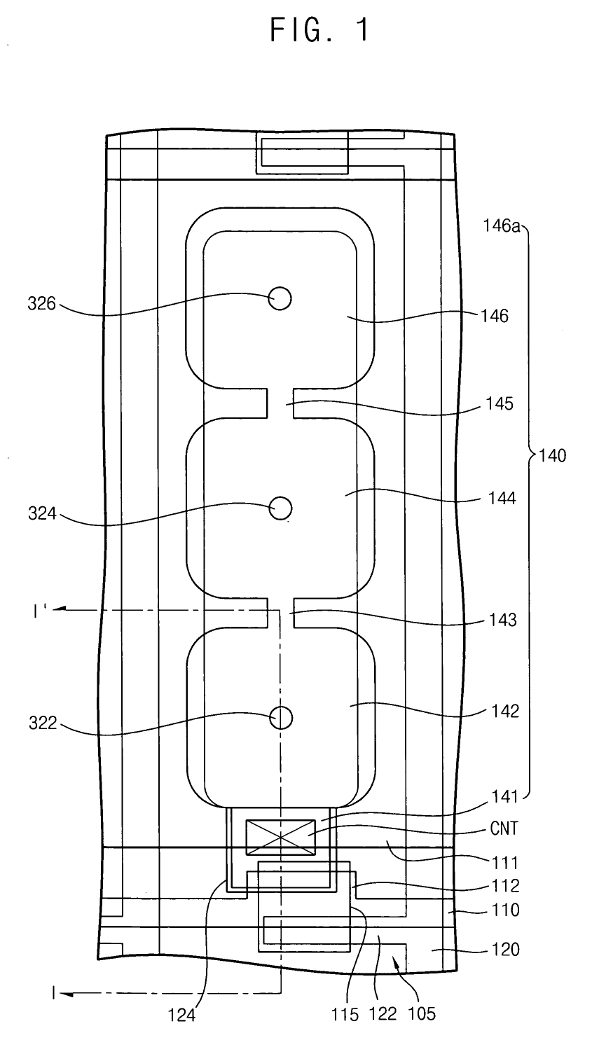

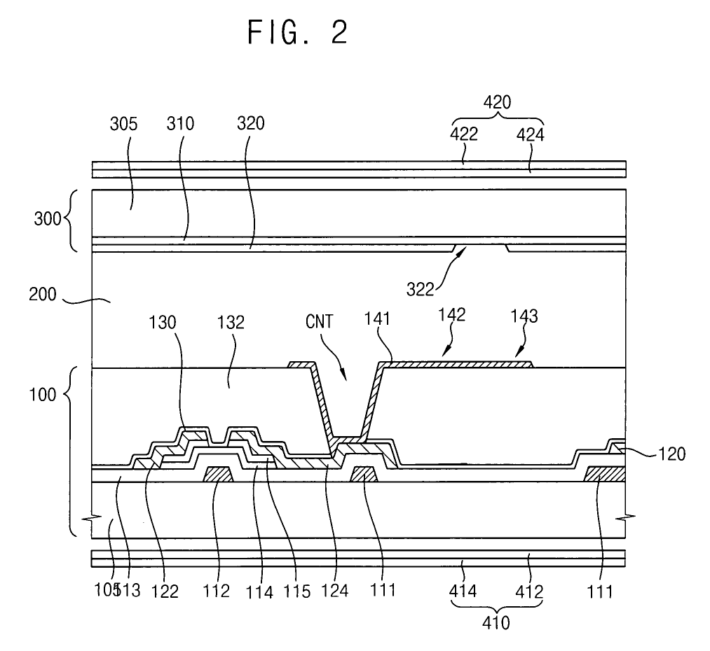

FIG. 1 is a plan view showing a portion of a liquid crystal display device according to an embodiment of the present invention, and FIG. 2 is a cross-sectional view taken along a line I-I′ in FIG. 1. Particularly, FIGS. 1 and 2 show a transmissive type liquid crystal display device that includes an array substrate having three sub electrodes and a color filter substrate (or an opposite substrate) having holes corresponding to each center portion of the sub electrodes.

Referring to FIGS. 1 and 2, the liquid crystal display device includes an array substrate 100, a liquid crystal layer 200, a color filter substrate 300 combined with the array substrate 100 to receive the liquid crystal layer 200, a lower optical film part 410 disposed under the array substrate 100, and an upper optical film part 420 disposed over the color filter substrate 300.

The array substrate 100 includes a gate line 110, a gate electrode 112, a bottom pattern 111 and a gate-insulating layer 113. The gate line 110 is disposed on a transparent substrate 105 and extends in a horizontal direction. The gate electrode 112 is extended from the gate line 110. The bottom pattern 111 is separated from the gate line 110, and a portion of the bottom pattern 111 corresponding to a center portion of a unit pixel area is opened. The gate-insulating layer 113 covers the gate line 110 and the gate electrode 112. The gate-insulating layer 113 includes, for example, a silicon nitride (SiNx).

The array substrate 100 may further include a semiconductor layer 114 including a semiconductor material such as, for example, amorphous-silicon (a-Si), an impurity-implanted semiconductor layer 115 including an impurity-implanted semiconductor material such as, for example, n+ a-Si formed on the semiconductor layer 114, a source line 120 extending in a vertical direction, a source electrode 122 extended from the source line 120, and a drain electrode 124 separated from the source electrode 122. The gate electrode 112, the semiconductor layer 114, the impurity-implanted semiconductor layer 115, the source electrode 122 and the drain electrode 124 define a thin film transistor (TFT).

The gate line 110 and the source line 120 may be formed to have a single-layered structure or a double-layered structure. For example, when the gate line 110 and the source line 120 have the single-layered structure, the layer gate line 110 and the source line 120 may include aluminum (Al) or aluminum alloy such as (AlNd). In addition, for example, when the gate line 110 and the source line 120 have the double-layered structure, the gate line 110 and the source line 120 include a lower layer and an upper layer. The lower layer may include materials whose physical/chemical properties are superior such as, for example, chromium (Cr), molybdenum (Mo), and an alloy film of molybdenum. The upper layer may include materials having low resistivity such as, for example, aluminum (Al) or an alloy of aluminum (Al).

The array substrate 100 further includes a passivation layer 130 and an organic insulating layer 132, which are successively deposited. The passivation layer 130 and the organic insulating layer 132 cover the thin film transistor, and expose a portion of the drain electrode 124. The passivation layer 130 and the organic insulating layer 132 cover and protect the semiconductor layer 114 and the impurity-implanted semiconductor layer 115, which are disposed between the source electrode 122 and the drain electrode 124. Also, the passivation layer 130 and the organic insulating layer 132 electrically insulate the thin film transistor from a pixel electrode layer 140. The thickness of the liquid crystal layer 200 may be controlled through managing the thickness of the organic insulating layer 132. The passivation layer 130 is optional.

The array substrate 100 may further include the pixel electrode part 140 that is electrically connected to the drain electrode 124 of the thin film transistor through a contact hole CNT. The pixel electrode part 140 defines capacitance of a storage capacitor Cst by an area overlapped with the bottom pattern 111.

The pixel electrode part 140 includes a first connecting electrode 141 connected to the drain electrode 124, a first sub electrode 142 extended from the first connecting electrode 141, a second connecting electrode 143 extended from the first sub electrode 142, a second sub electrode 144 extended from the second connecting electrode 143, a third connecting electrode 145 extended from the second sub electrode 144, and a third sub electrode 146 extended from the third connecting electrode 145. The first, second and third sub electrodes 142, 144 and 146 have a substantially rounded quadrilateral shape. The second and the third connecting electrodes 143 and 145 have a relatively narrow width.

The color filter substrate 300 includes a color pixel layer 310 formed on a transparent substrate 305 (or a base substrate) and a common electrode layer 320 formed on the color pixel layer 310. The color filter substrate 300 is combined with the array substrate 100 to receive the liquid crystal layer 200. The liquid crystal molecules of the liquid crystal layer 200 are aligned in a vertical alignment (VA) mode.

The common electrode layer 320 covers the color pixel layer 310. A first hole 322, a second hole 324 and a third hole 326 are formed at the common electrode layer 320 to correspond to each center portion of the first, the second and the third sub electrodes 142, 144 and 146, respectively. An electric field applied to a region where the first, second and third holes 322, 324 and 326 are formed is different from an electric field applied to a region where the first, second and third holes 322, 324 and 326 are not formed. Accordingly, the liquid crystal layer 200 is divided into a plurality of domains.

The lower optical film part 410 is disposed under the array substrate 100 and includes a first biaxial film 412 and a first polarizing film 414 integrally formed with the first biaxial film 412. The first biaxial film 412 is disposed relatively near to the array substrate 100. The above-mentioned term ‘biaxial’ as used herein means that refractive indexes in the x-axis direction, the y-axis direction and the z-axis direction are different from one another, wherein the x-axis direction represents a direction in which a refractive index of a phase retardation film is the maximum, the y-axis direction represents a direction substantially perpendicular to the x-axis on the plane of the film, and the z-axis direction represents a thickness-wise direction that means a direction substantially perpendicular to the surface of the retardation film. In other words, the above may also be represented as nx≠ny≠nz when nx, ny and nz denote refractive indexes in x-axis, y-axis and z-axis directions, respectively.

The surface-wise directional retardation Ro of the first biaxial film 412 is, for example, λ/4, which is in a range from about 120 nanometers (nm) to about 160 nm. The thickness-wise directional retardation Rth is in a range from about 130 nm to about 160 nm. When light whose wavelength is 560 nm is used as standard light, the surface-wise directional retardation Ro of the first biaxial film 412 is in a range of about 140±14 nanometers (nm).

The surface-wise directional retardation Ro of the first biaxial film and the thickness-wise directional retardation Rth are defined as the following Equation 1 and Equation 2.
Ro=(nx−ny)×d Equation 1

$$Rth = ( \frac{nx + ny}{2} - nz ) \times d \qquad Equation 2$$

In this equation, ‘nx’ represents a refractive index in a lag phase axis direction in which the refractive index is the maximum, ‘ny’ represents a refractive index in a lead phase axis direction that means a direction in which the refractive index is the minimum. Also, ‘nz’ is a refractive index in a thickness-wise direction of the film and ‘d’ is thickness of the film expressed in nanometers (nm).

The first biaxial film 412 and the first polarizing film 414 are disposed such that an angle between a slow axis of the first biaxial film 412 and a transmissive axis of the first polarizing film 414 is in a range of about 45±20 degrees. The transmissive axis of the first polarizing film 414 is tilted by about 45 degrees in a clockwise direction with respect to the slow axis of the first biaxial film 412 on the plane of the film.

The upper optical film part 420 includes a second biaxial film 422 and a second polarizing film 424 formed integrally with the second biaxial film 422. The upper optical film part 420 is disposed over the color filter substrate 300. The second biaxial film 422 is disposed relatively near to the color filter substrate 300. The surface-wise directional retardation Ro of the second biaxial film 422 is, for example, λ/4, which is from about 120 nm to about 160 nm. Thickness-wise directional retardation Rth is from about 130 nm to about 160 nm.

The second biaxial film 422 and the second polarizing film 424 are disposed such that an angle between a slow axis of the second biaxial film 422 and a transmissive axis of the second polarizing film 424 is in a range of about 45±20 degrees. The transmissive axis of the second polarizing film 424 is tilted by about 45 degrees in a clockwise direction with respect to the slow axis of the second biaxial film 422 on the plane of the film. Accordingly, the angle between the transmissive axis of the first polarizing film 414 and the transmissive axis of the second polarizing film 424 is about 90 degrees, and the angle between the slow axis of the first biaxial film 412 and the slow axis of the second biaxial film 422 is about 90 degrees.

The first, the second and the third sub electrodes 142, 144 and 146 electrically connected with each other are formed in a unit pixel area of the array substrate 100. The first, the second and the third holes 322, 324 and 326 are formed at the common electrode layer 320 to correspond to each center portion of the first, the second and the third sub electrodes 142, 144 and 146, respectively. Therefore, a process to align the liquid crystal molecules in a predetermined direction by rubbing the surface on an alignment film, which is formed on the array or color filter substrate, may be omitted. Also, the alignment film may not be required .

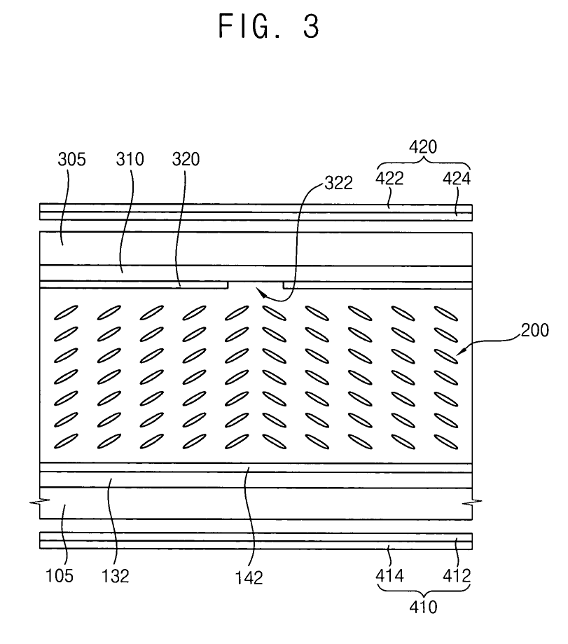

The unit pixel area of the array substrate partitioned into three sub pixel electrodes, and holes corresponding to each center portion of the partitioned sub pixel electrodes are formed at the common electrode layer of the color filter substrate so that a multi-domain may be materialized in a unit pixel area as shown in the following FIG. 3.

FIG. 3 is a cross-sectional view for explaining an operation of a liquid crystal display device shown in FIG. 1.

Referring to FIG. 3, liquid crystal molecules maintain a vertical alignment when a voltage is not applied. When a voltage is applied, the liquid crystal molecules lie down by a predetermined angle with respect to a fringe field so that the liquid crystal molecules are aligned. When the sub electrode 142 of the array substrate 100 is taken as a unit, for example, the liquid crystal molecules, which have aligned in a vertical direction, lie down in response to the applied voltage and converge to the hole 322 that is formed at the common electrode layer 320 of the color filter substrate 300 so that the liquid crystal molecules are aligned.

As mentioned above, sub electrodes 142, 144 and 146 are patterned in a unit pixel area of the array substrate 100, and holes 322, 324 and 326 corresponding to each center portion of the sub electrodes are formed at the color filter substrate 300 so that a multi-domain may be materialized.

In a plan view, directors of the liquid crystal molecules converge to center portions of the sub pixel electrodes so that a texture is formed along a transmissive axis even when a polarizing film is employed. The term ‘director’ as used herein means a major axial direction of the liquid crystal molecule. However, when the lower optical film part 410 is disposed under the array substrate 100 and the upper optical film part 420 is disposed over the color filter substrate 300, the texture disappears.

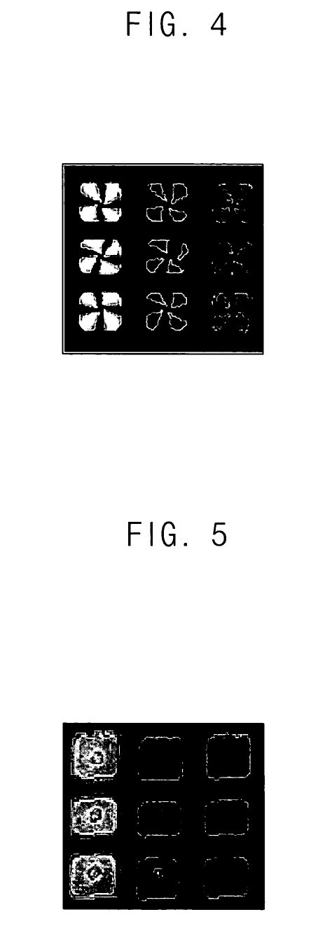

FIG. 4 is an image showing a texture observed in a liquid crystal display device having a multi-domain, and FIG. 5 is an image showing that the texture in FIG. 4 is eliminated because of the optical film assembly according to an exemplary embodiment of the present invention.

As shown in FIG. 4, a vane-shaped texture is observed at each center portion of the three sub pixel electrodes formed in a unit pixel.

However, as shown in FIG. 5, the texture is not shown when optical film parts, which include a biaxial film and a polarizing film, are disposed under and over a liquid crystal display panel.

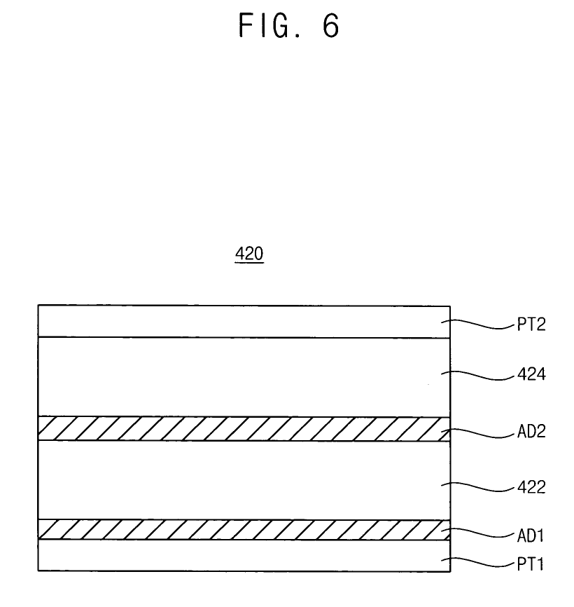

FIG. 6 is a cross-sectional view to explain an optical film part. Particularly, FIG. 6 shows an upper optical film part disposed over a color filter substrate.

Referring to FIG. 6, an upper optical film part 420 includes a first protecting film PT1, a second biaxial film 422 formed over the first protecting film PT1, a first adhesive layer AD1 formed between the first protecting film PT1 and the second biaxial film 422, a first polarizing film 424 formed over the second biaxial film 422, a second adhesive layer AD2 formed between the second biaxial film 422 and the first polarizing film 424, and a second protecting film PT2 formed over the first polarizing film 424. The first protecting film PT1 is disposed relatively near to the color filter substrate 300 shown in FIG. 2, and the second protecting film PT2 is disposed relatively far from the color filter substrate 300.

As depicted in FIG. 6, the upper optical film part 420 is disposed at the front surface of a color filter substrate 300. Additionally, a lower optical film part disposed at a rear surface of an array substrate may be described as a mirror symmetric structure of the upper optical film part.

As mentioned above, according to embodiments of the present invention, an optical film is employed in a liquid crystal display device having a multi domain, which is defined by sub-electrodes formed at an array substrate and holes formed at a common electrode of a color filter substrate, and includes a polarizing film and a biaxial film that are combined together, thereby resulting in a thin optical film and/or a thin liquid crystal display device having the optical film which may be manufactured at a reduced cost. Herein, the surface-wise directional retardation Ro of the first biaxial film 412 is λ/4, and thickness-wise directional retardation Rth of the first biaxial film 412 is about 160 nm.

In contrast, conventional optical films employed in a display device include a C-plate, a λ/4 phase retardation film and a polarizing film, which are successively disposed. According to embodiments of the present invention, the biaxial film substitutes for the C-plate and the λ/4 phase retardation film so that the thickness and the manufacturing costs for a device may be reduced.

The C-plate can be classified as either a positive C-plate or a negative C-plate. For example, a C-plate can be classified as either a positive C-plate or a negative C-plate according to the relationship of magnitude between refractive index ‘ne’ in an extraordinary axis and refractive index ‘no’ in an ordinary axis direction of an optical axis. In the case of the positive C-plate, refractive index ‘nx’ in x-axis direction is substantially the same as refractive index ‘ny’ in y-axis direction and substantially smaller than refractive index ‘nz’ in z-axis direction. In the case of the negative C-plate, refractive index ‘nx’ in x-axis direction is substantially the same as refractive index ‘ny’ in y-axis direction and substantially larger than refractive index ‘nz’ in z-axis direction.

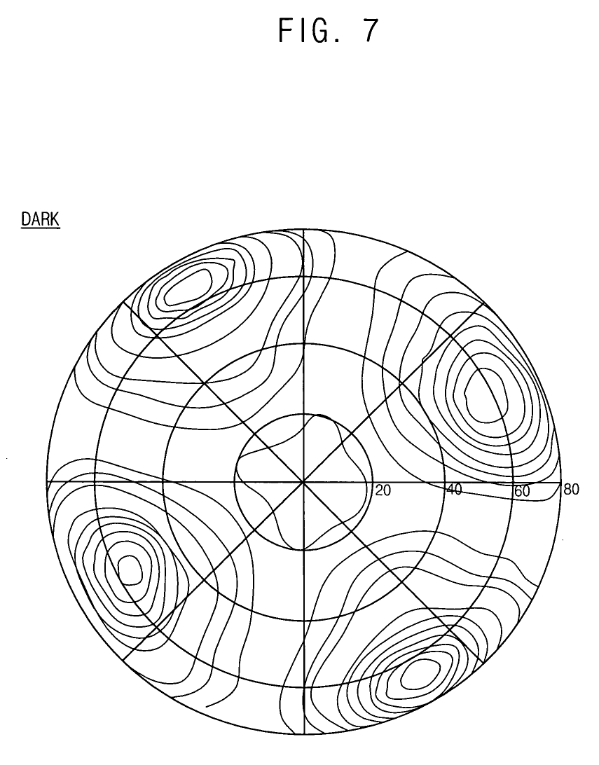

FIGS. 7, 8 and 9 are graphs to explain a viewing angle characteristic of a liquid crystal display device having an optical film according to an embodiment of the present invention. Particularly, the optical film in this embodiment of the present invention includes a relatively thick polarizing film and a biaxial film, wherein the ratio Ro/Rth of the surface-wise directional retardation Ro to thickness-wise directional retardation Rth of the biaxial film is in a range of from about 140 to about 130.

FIG. 7 is a graph showing the viewing angle characteristic in ‘dark’ mode. The viewing angle characteristic in ‘dark’ mode is full black in all directions when the viewing angle is below about 30 degrees. In the one o'clock, four o'clock, seven o'clock and ten o'clock directions, the viewing angle characteristic in ‘dark’ mode is gray when the viewing angle is from about 0 to about 90 degrees. In the two o'clock, five o'clock, eight o'clock and eleven o'clock directions, the viewing angle characteristic in ‘dark’ mode is white when the viewing angle is over about 60 degrees.

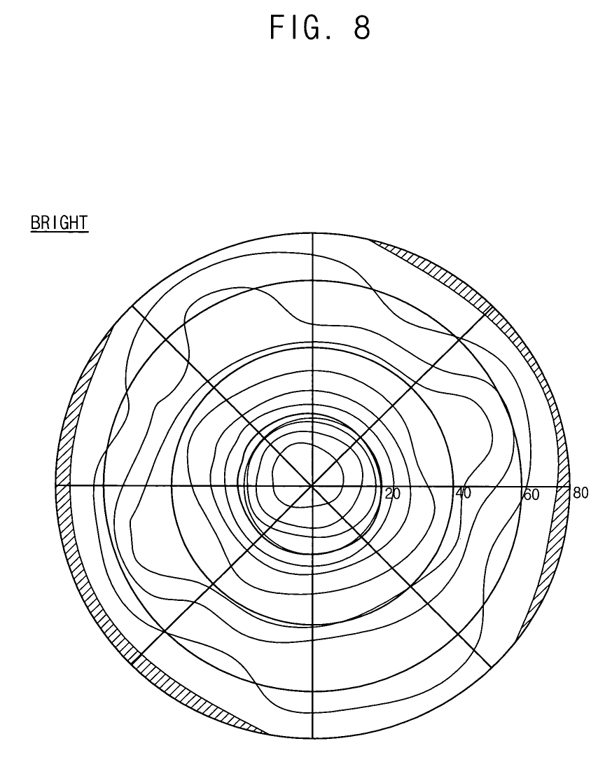

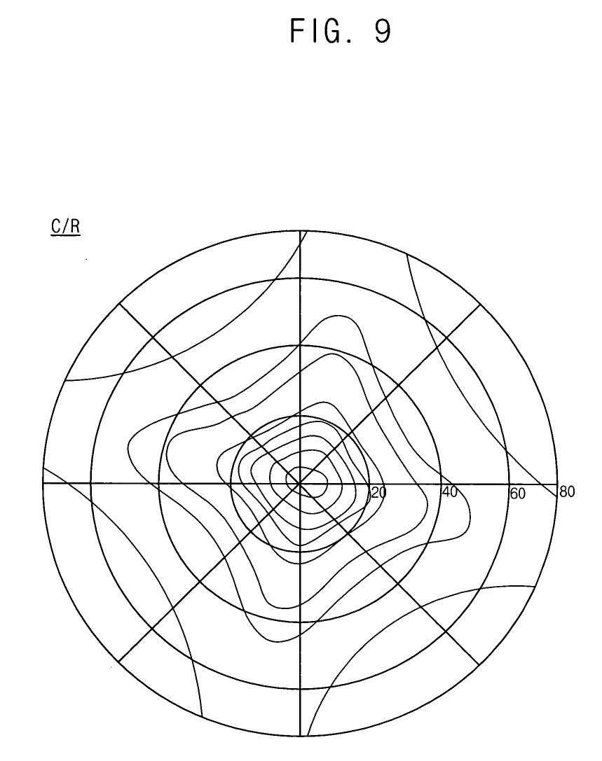

FIG. 8 is a graph showing the viewing angle characteristic in ‘bright’ mode. The viewing angle characteristic in ‘bright’ mode is full white in all directions when the viewing angle is below about 50 degrees, gray in all directions when the viewing angle is from about 50 to about 70 degrees, and black in all directions when the viewing angle is over about 70 degrees.

FIG. 9 is a graph showing a contrast ratio of the viewing angle characteristic in dark mode shown in FIG. 7 to the viewing angle characteristic in bright mode shown in FIG. 8.

Referring to FIG. 9, when an optical film according to an embodiment of the present invention is employed, the contrast ratio characteristic is improved in all directions when the viewing angle is below about 50 degrees. Also, in the one o'clock, four o'clock, seven o'clock and ten o'clock directions, the contrast ratio characteristic is relatively improved when the viewing angle is from about 60 to about 80 degrees.

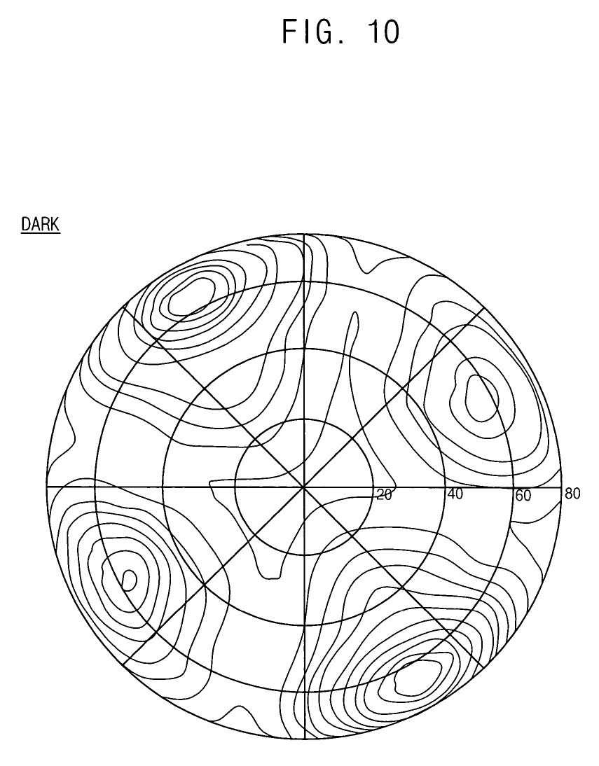

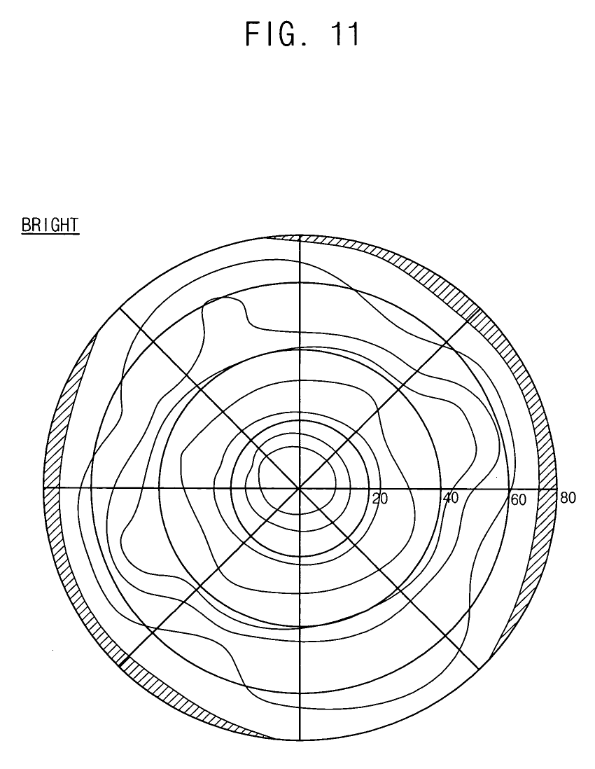

FIGS. 10, 11 and 12 are graphs to explain a viewing angle characteristic of a liquid crystal display device having an optical film according to an embodiment of the present invention. Particularly, the optical film according to this embodiment of the invention includes a relatively thin polarizing film and a biaxial film, herein, a ratio Ro/Rth of the surface-wise directional retardation Ro to thickness-wise directional retardation Rth of the biaxial film is about 140 to about 175.

FIG. 10 is a graph showing the viewing angle characteristic in ‘dark’ mode. The viewing angle characteristic is full black in all directions when the viewing angle is below about 10 degrees. In the one o'clock, three o'clock, seven o'clock and nine o'clock directions, the viewing angle characteristic is full black when the viewing angle is about 30 degrees. In the one o'clock, four o'clock, seven o'clock and ten o'clock directions, the viewing angle characteristic is gray when the viewing angle is from about 30 to about 90 degrees. In the two o'clock, five o'clock, eight o'clock and eleven o'clock directions, the viewing angle characteristic is white when the viewing angle is over about 60 degrees.

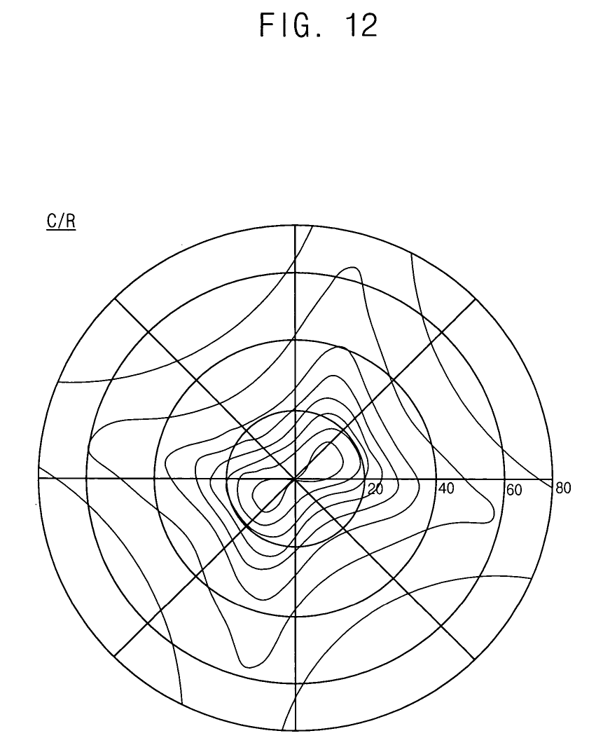

FIG. 11 is a graph showing the viewing angle characteristic in ‘bright’ mode. The viewing angle characteristic is full white in all directions when the viewing angle is below about 50 degrees, gray in all directions when the viewing angle is from about 50 to about 70 degrees, and black in all directions when the viewing angle is over about 70 degrees.

FIG. 12 is a graph showing a contrast ratio of the viewing angle characteristic in dark mode shown in FIG. 10 to the viewing angle characteristic in bright mode shown in FIG. 11.

Referring to FIG. 12, when an optical film according to the present embodiment of the invention is employed, the contrast ratio characteristic is improved in all directions when the viewing angle is below about 50 degrees. Also, in the one o'clock, four o'clock, seven o'clock and ten o'clock directions, the contrast ratio characteristic is relatively improved when the viewing angle is from about 50 to about 80 degrees.

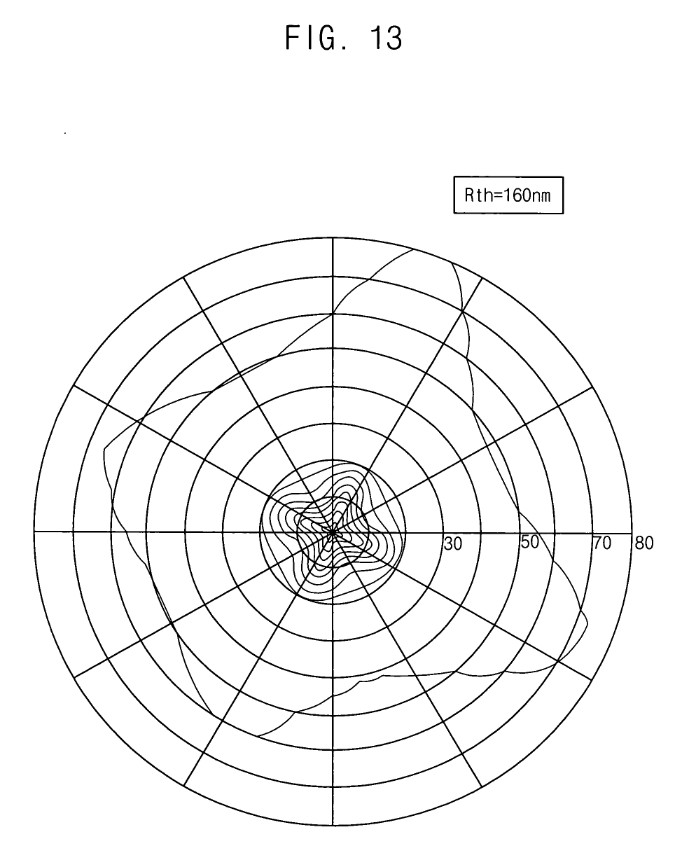

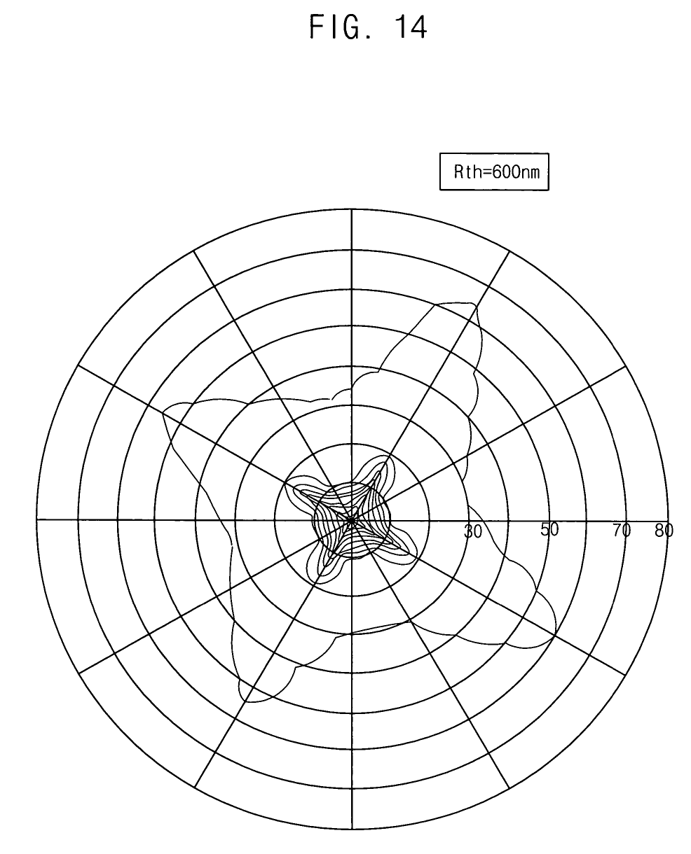

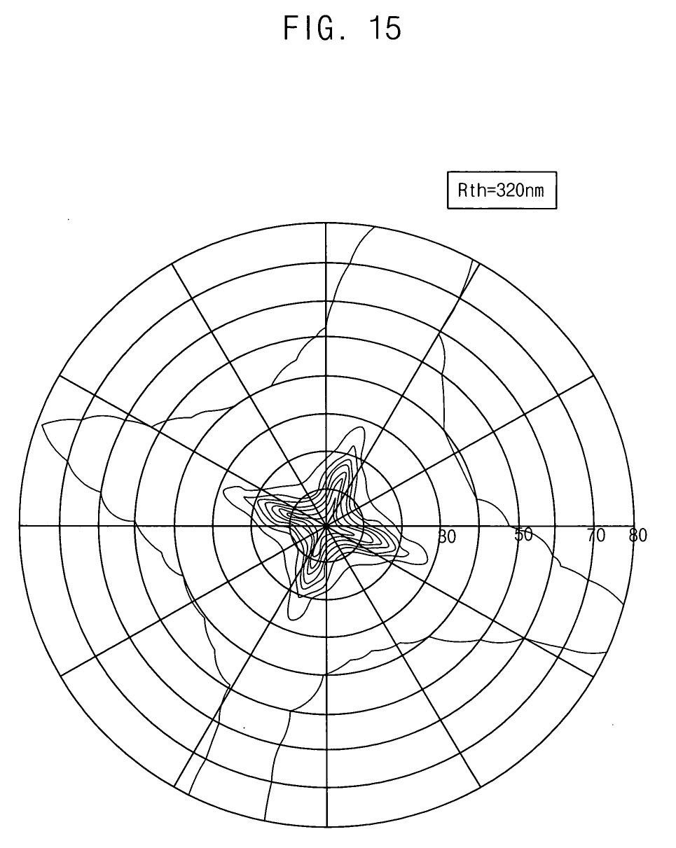

FIGS. 13, 14 and 15 are graphs to explain a contrast ratio according to a change of thickness-wise directional retardation Rth of a biaxial film. Particularly, FIG. 13 is a graph to explain a contrast ratio corresponding to a thickness-wise directional retardation Rth of about 160 nm along a thickness-wise direction of a biaxial film according to an embodiment of the present invention. FIG. 14 is a graph to explain a contrast ratio corresponding to a thickness-wise directional retardation Rth of about 600 nm along a thickness-wise direction of a biaxial film according to another embodiment of the present invention. FIG. 15 is a graph to explain a contrast ratio corresponding to a thickness-wise directional retardation Rth of about 320 nm along a thickness-wise direction of a biaxial film according to still another embodiment of the present invention.

As shown in FIG. 13, the contrast ratio of a liquid crystal display device having a biaxial film according to an embodiment of the present invention, whose thickness-wise directional retardation Rth is about 160 nanometers (nm), is relatively improved in all directions when the viewing angle is below about 40 degrees.

A viewing angle of about 80 degrees may be obtained in a direction ranging from about twelve o'clock to about one o'clock, from about three o'clock to about four o'clock, from about six o'clock to about seven o'clock, and from about nine o'clock to about eleven o'clock.

As shown in FIG. 14, the viewing angle characteristic of a liquid crystal display device having an biaxial film according to an embodiment of the present invention, whose thickness-wise directional retardation Rth is about 600 nanometers (nm), is relatively improved in all directions when the viewing angle is below about 30 degrees.

A viewing angle of about 60 degrees may be obtained in a direction ranging from about twelve o'clock to about one o'clock and in the four o'clock direction. A viewing angle of about 50 degrees may be obtained in the seven o'clock and ten o'clock directions.

As shown in FIG. 15, the viewing angle characteristic of a liquid crystal display device having an biaxial film according to an embodiment of the present invention, whose thickness-wise directional retardation Rth is about 320 nanometers (nm), is relatively improved in all directions when the viewing angle is below about 40 degrees.

A viewing angle of up to about 80 degrees may be obtained in a direction ranging from about twelve o'clock to about one o'clock, and a viewing angle of about 70 degrees may be obtained in a direction raging from about three o'clock to about four o'clock, and a viewing angle of about 60 degrees may be obtained in the seven o'clock and in a direction ranging from nine o'clock to ten o'clock.

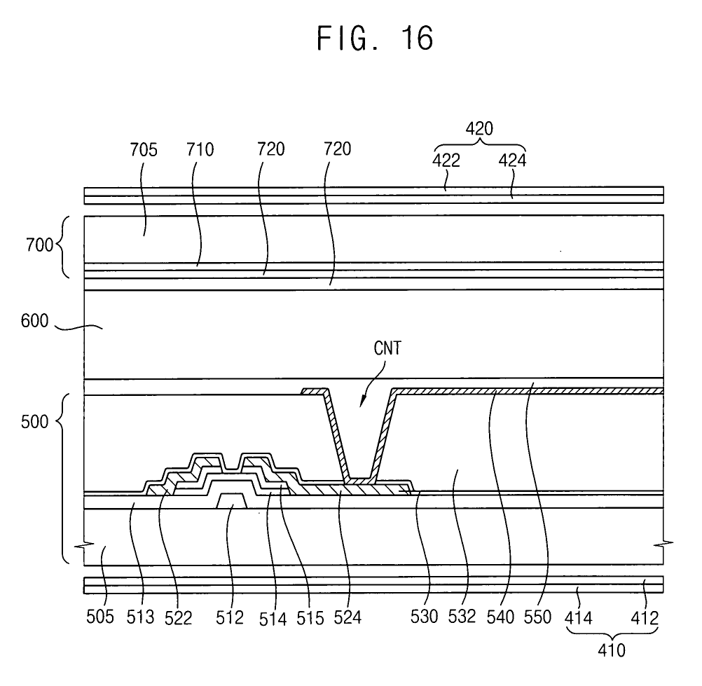

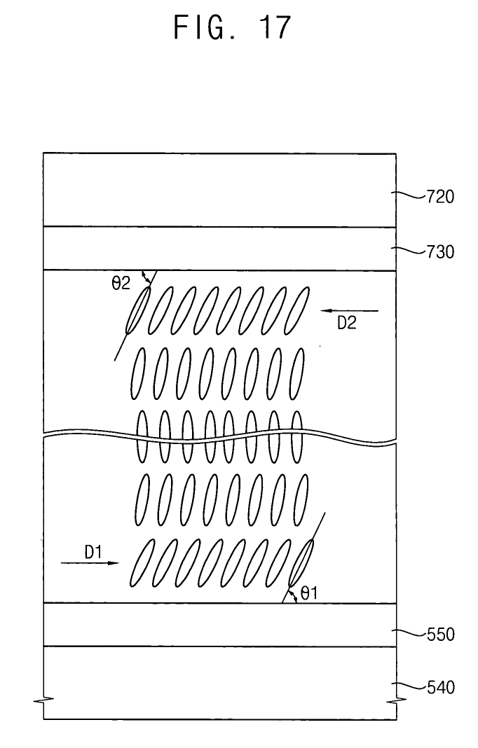

FIG. 16 is a cross-sectional view showing a liquid crystal display device according to another embodiment of the present invention. FIG. 17 is a cross-sectional view showing simply the liquid crystal layer shown in FIG. 16. The liquid crystal display device in this embodiment, includes a liquid crystal display panel having a RVA (Rubbed vertical alignment) structure. Alignment films of an upper substrate and a bottom substrate of the liquid crystal display panel are rubbed in different directions.

Referring to FIGS. 16 and 17, the liquid crystal display device includes an array substrate 500, a liquid crystal layer 600, a color filter substrate 700 receiving the liquid crystal layer 600 through being combined with the array substrate 500, a lower optical film part 410 disposed under the array substrate 500, and an upper optical film part 420 disposed over the color filter substrate 700. The lower optical film part 410 and the upper optical film part 420 were already described in FIGS. 2 to 6. Therefore, the same reference number will be used to refer to the same or similar parts as those described in FIGS. 2 to 6 and any further explanations concerning the above elements will be omitted.

The array substrate 500 includes a gate line 510 extending in a horizontal direction on a transparent substrate 505, a gate electrode 512 extended from the gate line 510, and a gate insulating layer 513 covering the gate line 510 and the gate electrode 512. The gate-insulating layer 513 includes, for example, silicon nitride (SiNx).

The array substrate 500 may further include a semiconductor layer 514 such as, for example, amorphous-silicon (a-Si), an impurity-implanted semiconductor layer 515 such as, for example, n+ a-Si formed on the semiconductor layer 514, a source line 520 extending in a vertical direction, a source electrode 522 extended from the source line 520, and a drain electrode 524 separated by a predetermined distance from the source electrode 522. The gate electrode 512, the semiconductor layer 514, the impurity-implanted semiconductor layer 515, the source electrode 522 and the drain electrode 524 define a thin film transistor (TFT).

The array substrate 500 may further include a passivation layer 530 and an organic insulating layer 532, which are successively deposited. The passivation layer 530 and the organic insulating layer 532 cover the thin film transistor, and expose a portion of the drain electrode 524. The passivation layer 530 and the organic insulating layer 532 cover and protect the semiconductor layer 514 and the impurity-implanted semiconductor layer 515, which are disposed between the source electrode 522 and the drain electrode 524. Also, the passivation layer 530 and the organic insulating layer 532 electrically insulate the thin film transistor from a pixel electrode layer 540. The thickness of the liquid crystal layer 600 may be controlled through managing the thickness of the organic insulating layer 532. The passivation layer 530 is optional.

The array substrate 500 may further include a pixel electrode part 540, which is electrically connected to the drain electrode 524 of the thin film transistor through a contact hole CNT, and a first alignment film 550 formed over the pixel electrode part 540. The first alignment film 550 is rubbed, for example, in a right direction D1 viewed by an observer.

The color filter substrate 700 includes a color pixel layer 710 formed on the transparent substrate 705 (or a base substrate), a common electrode layer 720 formed on the color pixel layer 710, and a second alignment film 730 formed under common electrode layer 720. The color filter substrate 700 is combined with the array substrate 500 to receive the liquid crystal layer 600. The liquid crystal molecules of the liquid crystal layer 600 are aligned in a vertical alignment (VA) mode.

The second alignment film 730 is rubbed, for example, in a left direction D2 viewed by an observer.

The first alignment film 550 formed at the array substrate 500 is rubbed in a right direction D1, and the second alignment film 730 formed at the color filter substrate 700 is rubbed in a left direction D2 so that the liquid crystal molecules are aligned in a vertical direction, in which an alignment angle is approximately 90 degrees. For example, a first initial inclined angle ‘θ1’ owing to the first alignment film 550 or a second initial inclined angle ‘θ2’ owing to the second alignment film 730 ranges from about 88 degrees to about 89.5 degrees.

As mentioned above, with an optical film assembly and a liquid crystal display device having the optical film assembly according to embodiments of the present invention, a biaxial film, whose surface-wise directional retardation Ro is λ/4 and thickness-wise directional retardation Rth is about 160 nm, is disposed near to a liquid crystal display panel, and a polarizing film adheres to the biaxial film so that a thin optical film may be obtained and the costs of manufacturing the optical film or a liquid crystal display device having the optical film may be reduced.

Having described the exemplary embodiments of the present invention, it is further noted that it is readily apparent to those of reasonable skill in the art that various modifications may be made without departing from the spirit and scope of the invention, which is defined by the metes, and bounds of the appended claims.

What is claimed is:

1. A liquid crystal display device comprising:
a liquid crystal display panel including two substrates and a liquid crystal layer disposed between the substrates, the liquid crystal display panel having a plurality of multi-domains defined in a unit pixel; and
an optical film assembly disposed under and over the liquid crystal display panel, the optical film comprising a biaxial film and a polarizing film formed integrally with the biaxial film, the biaxial film being disposed near the liquid crystal display panel.

2. The liquid crystal display device of claim 1, wherein the liquid crystal display panel includes:
an array substrate having a pixel electrode; and
an opposing substrate, which faces the array substrate and has a common electrode, which comprises a hole,
wherein a hole is formed at the common electrode to define the multi-domains, and the hole is formed to correspond to a center of the pixel electrode, respectively.

3. The liquid crystal display device of claim 2, wherein the polarizing film is relatively thick and a Ro/Rth for the biaxial film is about 140/130, and wherein Ro is surface-wise directional retardation and Rth is thickness-wise directional retardation.

4. The liquid crystal display device of claim 2, wherein the polarizing film is relatively thin and a Ro/Rth for the biaxial film is about 140/175, and wherein Ro is surface-wise directional retardation and Rth is thickness-wise directional retardation.

5. The liquid crystal display device of claim 3 or claim 4, wherein the surface-wise directional retardation Ro of the biaxial film is λ/4.

6. The liquid crystal display device of claim 5, wherein the surface-wise directional retardation Ro of the biaxial film is in a range of from about 120 nm to about 160 nm.

7. The liquid crystal display device of claim 6, wherein the surface-wise ‘directional retardation Ro of the biaxial film is in a range of from about 126 nm to about 154 nm and wherein a wavelength of standard light is about 560 nm.

8. The liquid crystal display device of claim 1, wherein retardation in a thickness-wise direction of the biaxial film is about 130 nm and the polarizing film is relatively thin

9. The liquid crystal display device of claim 1, wherein retardation in a thickness-wise direction of the biaxial film is about 160 nm and the polarizing film is relatively thick.

10. The liquid crystal display device of claim 1, wherein an angle between a slow axis of the biaxial film and a transmissive axis of the polarizing film is about 25 degrees to about 65 degrees.

11. The liquid crystal display device of claim 10, wherein the transmissive axis of the polarizing film is positioned about 45 degrees in a clockwise direction with respect to the slow axis of the biaxial film.

12. A liquid crystal display device comprising:
a liquid crystal display panel comprising two substrates and a liquid crystal layer disposed between the substrates, liquid crystal molecules of the liquid crystal layer being aligned at an angle of about 90 degrees with respect to the substrates; and
an optical film assembly disposed under and over the liquid crystal display panel, the optical film comprising a biaxial film and a polarizing film formed integrally with the biaxial film, the biaxial film being disposed near the liquid crystal display panel.

13. The liquid crystal display device of claim 12, wherein the liquid crystal display panel comprises:
an array substrate having a pixel electrode and a first alignment film rubbed in a first direction; and
an opposing substrate having a common electrode and a second alignment film rubbed in a second direction opposite to the first direction, wherein the opposing substrate faces and is combined with the array substrate, with the liquid crystal layer being disposed between the array substrate and the opposite substrate.

14. The liquid crystal display device of claim 12, wherein the liquid crystal molecules of the liquid crystal layer, which make contact with the first alignment film, have an initial inclined angle in a range of from about 88 degrees to about 89.5 degrees with respect to the first alignment film.

15. The liquid crystal display device of claim 14, wherein the liquid crystal molecules of the liquid crystal layer, which make contact with the second alignment film, have an initial inclined angle in a range of from about 88 degrees to about 89.5 degrees with respect to the second alignment film.

16. The liquid crystal display device of claim 12, wherein the polarizing film is relatively thick and a Ro/Rth for the biaxial film is about 140/130, and wherein Ro is surface-wise directional retardation, and Rth is thickness-wise directional retardation.

17. The liquid crystal display device of claim 12, wherein the polarizing film is relatively thin and a Ro/Rth for the biaxial film is about 140/175, and wherein Ro is surface-wise directional retardation, and Rth is thickness-wise directional retardation.

18. The liquid crystal display device of claim 16 or 17, wherein the surface-wise directional retardation Ro of the biaxial film is λ/4.

19. The liquid crystal display device of claim 18, wherein the surface-wise directional retardation Ro of the biaxial film is in a range of from about 120 nm to about 160 nm.

20. The liquid crystal display device of claim 19, wherein the surface-wise directional retardation Ro of the biaxial film is about in a range from about 126 nm to about 154 nm and wherein a wavelength of standard light is about 560 nm.

21. The liquid crystal display device of claim 12, wherein retardation in a thickness-wise direction of the biaxial film is about 130 nm and the polarizing film is relatively thin.

22. The liquid crystal display device of claim 12, wherein retardation in a thickness-wise direction of the biaxial film is about 160 nm and the polarizing film is relatively thick.

23. The liquid crystal display device of claim 12, wherein an angle between a slow axis of the biaxial film and a transmissive axis of the polarizing film is in a range from about 25 degrees to about 65 degrees.

24. The liquid crystal display device of claim 23, wherein the transmissive axis of the polarizing film is positioned about 45 degrees in a clockwise direction with respect to the slow axis of the biaxial film.

25. An optical film assembly changing a characteristic of light provided through a liquid crystal cell comprising:
a biaxial film disposed near the liquid crystal cell; and
a polarizing film disposed away from the liquid crystal cell, the polarizing film formed integrally with the biaxial film.

26. The optical film assembly of claim 25, wherein surface-wise directional retardation Ro of the biaxial film is λ/4.

27. The optical film assembly of claim 26, wherein retardation in a thickness-wise direction of the biaxial film is about 160 nm

28. The optical film assembly of claim 25, wherein the polarizing film is relatively thick and a Ro/Rth of the biaxial film is about 140/130, and wherein Ro is surface-wise directional retardation, and Rth is thickness-wise directional retardation.

29. The optical film assembly of claim 25, wherein the polarizing film is relatively thin and a Ro/Rth of the biaxial film is about 140/175, and wherein Ro is surface-wise directional retardation, and Rth is thickness-wise directional retardation.

30. The optical film assembly of claim 28 or 29, wherein surface-wise directional retardation Ro of the biaxial film is λ/4.

31. The optical film assembly of claim 30, wherein surface-wise directional retardation Ro of the biaxial film is in a range of from about 120 nm to about 160 nm.

32. The optical film assembly of claim 31, wherein surface-wise directional retardation Ro of the biaxial film is in a range from about 126 nm to about 154 nm and wherein a wavelength of standard light is about 560 nm.

33. The optical film assembly of claim 25, wherein retardation in a thickness-wise direction of the biaxial film is about 130 nm and the polarizing film is relatively thin.

34. The optical film assembly of claim 25, wherein retardation in a thickness-wise direction of the biaxial film is about 160 nm and the polarizing film is relatively thick.

35. The optical film assembly of claim 25, wherein an angular relationship between a slow axis of the biaxial film and a transmissive axis of the polarizing film is in a range from about 25 degrees to about 65 degrees.

36. The optical film assembly of claim 35, wherein the transmissive axis of the polarizing film is positioned about 45 degrees in a clockwise direction with respect to the slow axis of the biaxial film.

37. The optical film assembly of claim 25, wherein the biaxial film is disposed over the liquid crystal cell.

38. The optical film assembly of claim 37, wherein the biaxial film is disposed under the liquid crystal cell.

39. The optical film assembly of claim 25, further comprising:
a first adhesive layer disposed under the biaxial film; and
a second adhesive layer interposed between the biaxial film and the polarizing film.
